(19) United States
(12) Patent Application Publication
(10) Pub. No.: US 2010/0214742 A1
(43) Pub. Date: Aug. 26, 2010

(54) Heat-sinking memory module device

(75) Inventors: Charles W.C. Lin, Yunghe (TW); Wei-Kuang Pan, Taipei (TW); Chia-Chung Wang, Hsinchu (TW)

Correspondence Address: Jackson Intellectual Property Group PLLC, 106 Starvale Lane, Shipman, VA, 22971, US

(73) Assignee: Bridge Semiconductor Corporation, Taipei (TW)

(21) Appl. No.: 12/149,769

(22) Filed: May 7, 2008

(30) Foreign Application Priority Data
May 17, 2005 (TW) 096117666

(51) Int. Cl. H05K 7/20

(52) U.S. Cl. 361/690; 361/715

(57) ABSTRACT

A memory module has a good heat sinking effect. Each chip on the memory module has a surface exposed in the air. Or, a thermal pad can further adhere to the surface of the chips. Thus, the heat sinking effect of the memory module is improved; and an easy and convenient producing method is obtained.

### FIELD OF THE INVENTION

The present invention relates to a memory module; more particularly, relates to directly exposing chips on semiconductor components in air for improving a heat sinking effect and manufacture of the memory module.

### DESCRIPTION OF THE RELATED ART

A general memory module, as shown in FIG. 11 and FIG. 12, is a printed circuit board (PCB) 51 having a plurality of semiconductor components 52 inlayed on surface. When operation of the semiconductor components 52 on the PCB 51 becomes faster, more heat is generated by the chips 53 on the semiconductor components 52. Hence, effective heat sinking becomes important.

A general solution is to use a thermal pad adhering to the semiconductor components 52 through a thermal interface material (TIM). The TIM is silicon, which has a good heat sinking effect for dissipating heat through the thermal pad. However, the chips 53 are packaged in the semiconductor components 52 with a gel material 6. The TIM is not directly contact with the chips 53 in the semiconductor components 52, where the heat sinking effect is thus lowered. Hence, the prior art does not fulfill all users' requests on actual use.

### SUMMARY OF THE INVENTION

The main purpose of the present invention is to improve heat sinking effect of a memory module.

Another purpose of the present invention is to obtain an easy and economic manufacturing procedure of the memory module.

To achieve the above purposes, the present invention is a heat-sinking memory module device, comprising a memory module board; a plurality of semiconductor components on the memory module board; and a plurality of chips on the plurality of semiconductor components, where a surface of each chip is directly exposed in air; or, the semiconductor components are smeared with underfill or are packaged to be ground until a surface of each chip is directly exposed in air; or, the surfaces of the chips further adhere to a thermal pad through a TIM. Accordingly, a novel heat-sinking memory module device is obtained.

### BRIEF DESCRIPTION OF THE DRAWINGS

The present invention will be better understood from the following detailed descriptions of the preferred embodiments according to the present invention, taken in conjunction with the accompanying drawings, in which

FIG. 1 is the perspective view showing the first state of use of the first preferred embodiment according to the present invention;

FIG. 2 is the sectional view showing the first state of use of the first preferred embodiment;

FIG. 3 is the view showing area A in FIG. 2;

FIG. 4A is the sectional view showing the first state of use of the second preferred embodiment;

FIG. 4B is the sectional view showing the second state of use of the second preferred embodiment;

FIG. 5 is the perspective view showing the second state of use of the first preferred embodiment;

FIG. 6 is the sectional view showing the second state of use of the first preferred embodiment;

FIG. 7A is the explosive view showing the third state of use of the second preferred embodiment;

FIG. 7B is the explosive view showing the fourth state of use of the second preferred embodiment;

FIG. 8A is the assembled view showing the third state of use of the second preferred embodiment;

FIG. 8B is the assembled view showing the fourth state of use of the second preferred embodiment;

FIG. 9 is the sectional view showing the third state of use of the second preferred embodiment;

FIG. 10 is the view showing area B in FIG. 9;

FIG. 11 is the perspective view of the prior art; and

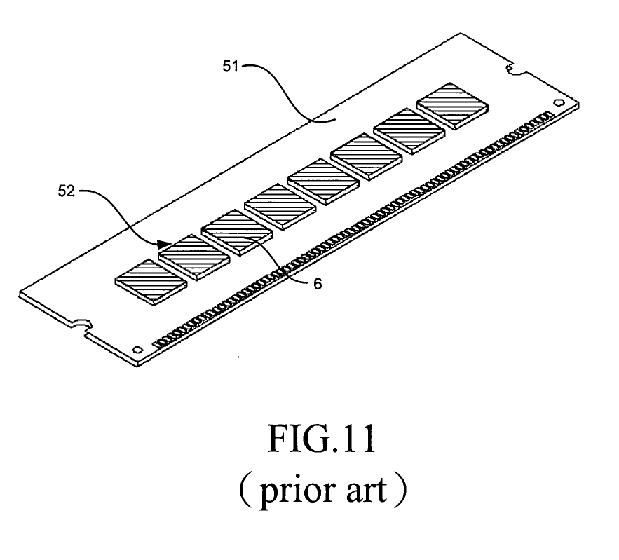

FIG. 12 is the sectional view of the prior art.

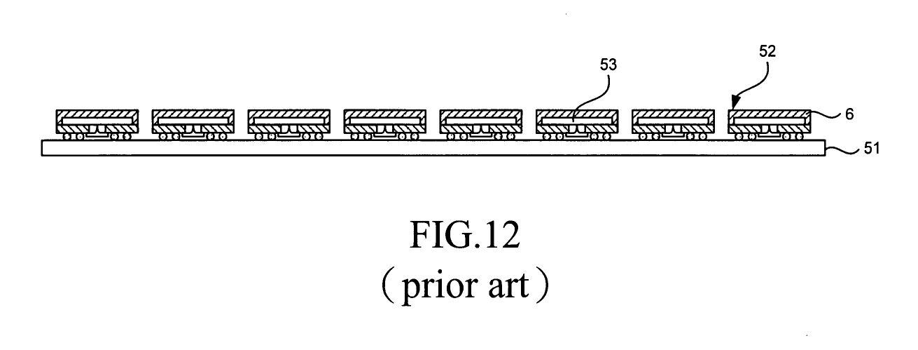

### DESCRIPTIONS OF THE PREFERRED EMBODIMENTS

The following descriptions of the preferred embodiments are provided to understand the features and the structures of the present invention.

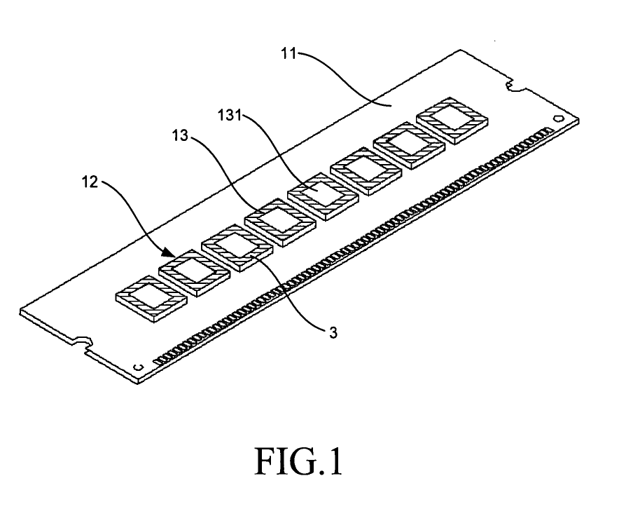

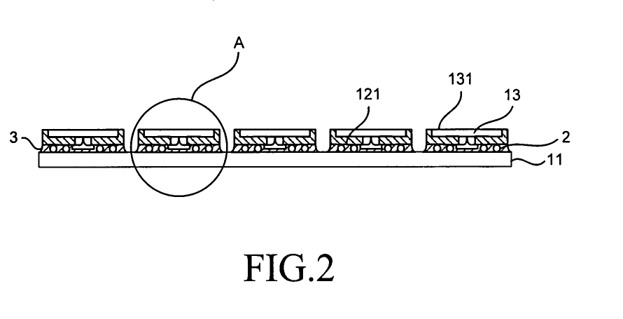

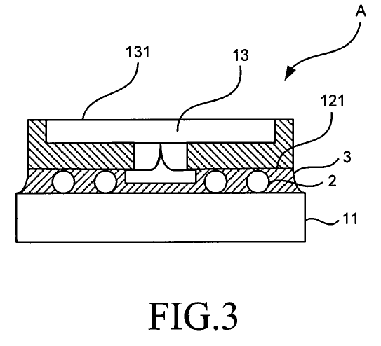

Please refer to FIG. 1 to FIG. 3, which are a perspective view showing a first state of use of a first preferred embodiment according to the present invention; a sectional view showing the first state of use; and a view showing area A in FIG. 2. As shown in the figures, the present invention is a heat-sinking memory module device, comprising a memory module board 11, a plurality of semiconductor components 12 and a plurality of chips 13, where heat sinking effect of a memory module is improved.

The memory module board 11 is deposed with the semiconductor components 12; and is connected with surfaces 121 of the semiconductor components 12 through tin balls 2. The chips 13 are deposed on the semiconductor components 12; and a surface of each chip 13 is exposed in air. Therein, the semiconductor components 12 are deposed on a side surface or both surfaces of the memory module board 11. Thus, a novel heat-sinking memory module device is obtained.

On assembling the present invention, the semiconductor components 12 are inlayed on the memory module board 11 with surfaces of the chips 13 directly exposed in air.

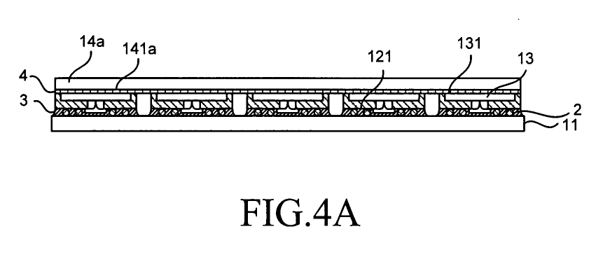

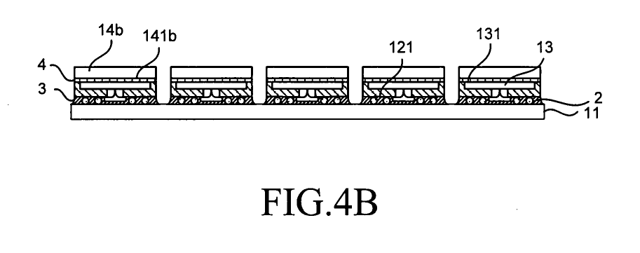

Please refer to FIG. 4A and FIG. 4B, which are sectional views showing a first state of use and a second state of use of a second preferred embodiment. As shown in the figures, a thermal pad 14a or a plurality of thermal pads 14b are adhered on the chips to dissipate heat generated from the semiconductor components 12, where the thermal pad 14a,14b is made of a metal or an alloy.

On assembling the present invention, a surface 131 of the chip adhere to a surface 141a,141b of the thermal pad 14a,14b through a thermal interface material (TIM) 4 of a gel material with a high heat-sinking effect; and, thus, the TIM is closely adhered on the memory module.

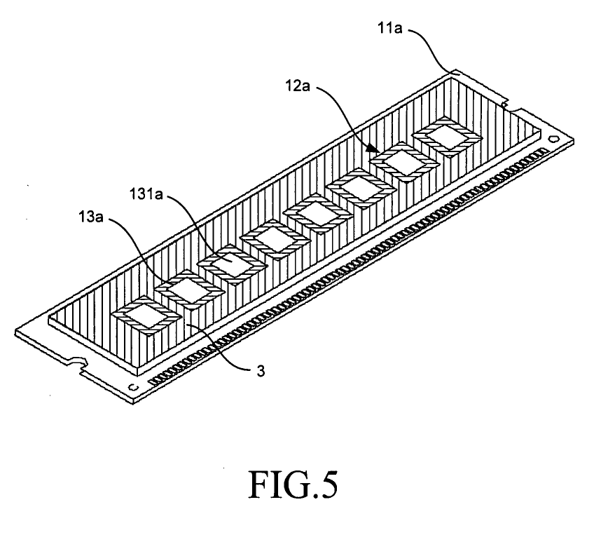

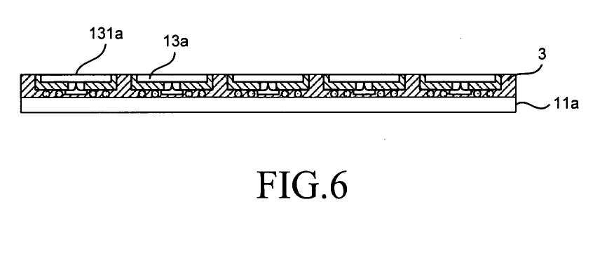

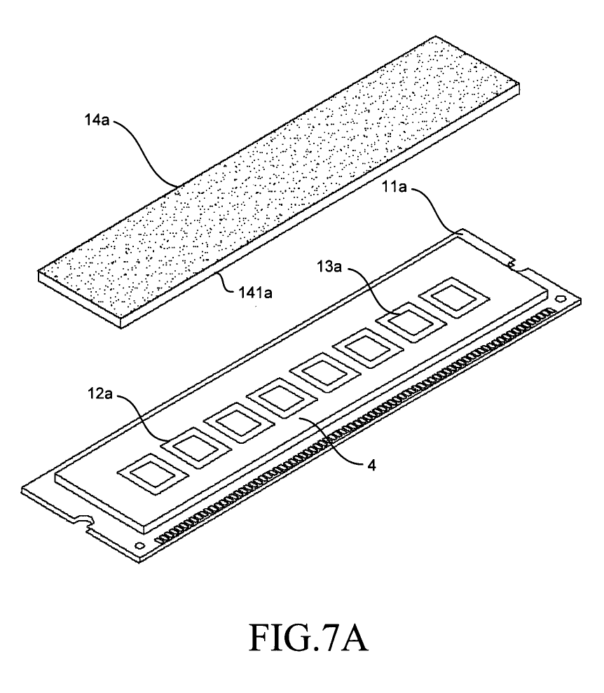

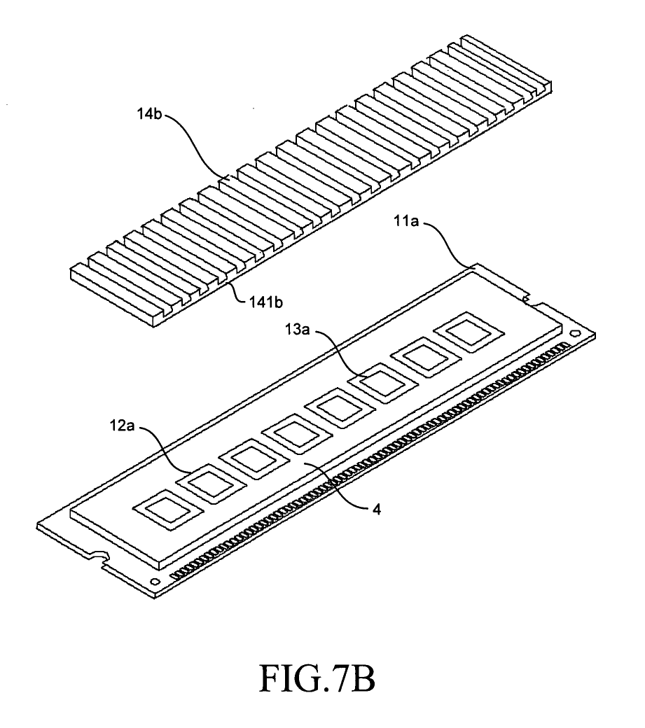

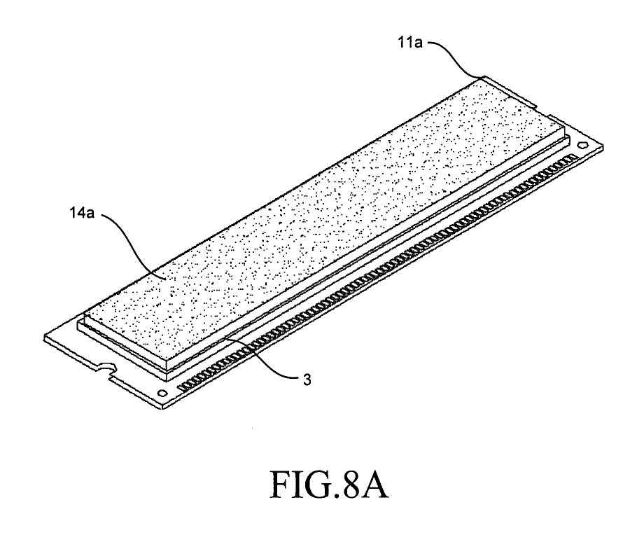

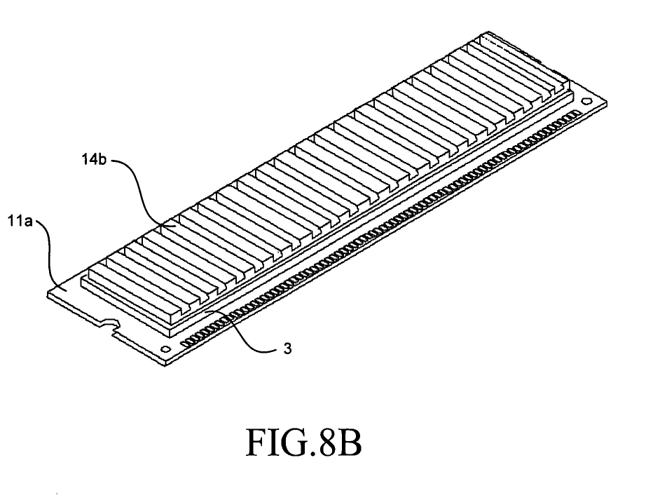

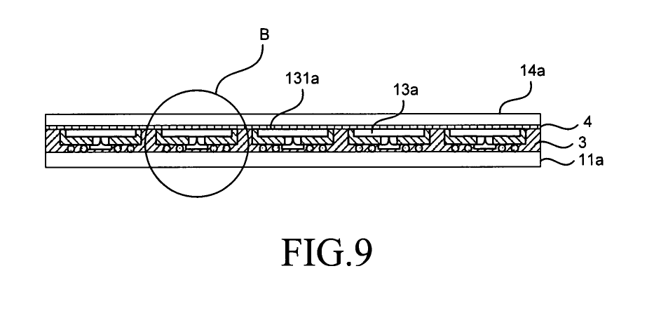

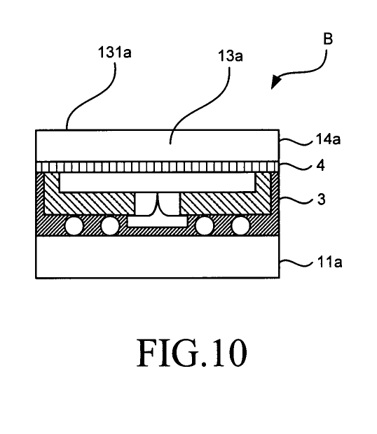

Please refer to FIG. 5 to FIG. 10, which are a perspective view and a sectional view showing a second state of use of the first preferred embodiment; explosive views showing a third state and a fourth state of use of the second preferred embodiment respectively; assembled views showing the third state and the fourth state of use of the second preferred embodiment respectively; a sectional view showing the third state of use of the second preferred embodiment; and a view showing area B in FIG. 9. As shown in the figures, a general memory module board 11a is obtained to be smeared with underfill 3 or is packaged. The memory module board 11a is ground until surfaces of chips 13a on semiconductor components 12a are totally exposed in air. Then a thermal pad 14a,14b is applied on each chip 13a to dissipate heat generated from the semiconductor components 12a. Therein, the thermal pad is made of a metal or an alloy.

On assembling the present invention, a surface 131a of the chip 13a is adhered to a surface 141a,141b of the thermal pad 14a,14b through a TIM 4 of a gel material with high heat-sinking effect; and, thus, the TIM is closely adhered on the memory module.

Hence, heat sinking effect of the memory module is improved through the first preferred embodiment. Nevertheless, in the second preferred embodiment, the thermal pad 14a,14b is adhered on the chips 13,13a to further improve the heat sinking effect of the memory module. Accordingly, the present invention not only improves the heat sinking effect of the memory module, but also obtains an easy and economic manufacturing procedure.

To sum up, the present invention is a heat-sinking memory module device, where, chips of the memory module device are directly exposed in air or further adhere to a thermal pad through a TIM for improving heat sinking effect; and, thus, an easy and economic manufacturing procedure is obtained.

The preferred embodiments herein disclosed are not intended to unnecessarily limit the scope of the invention. Therefore, simple modifications or variations belonging to the equivalent of the scope of the claims and the instructions disclosed herein for a patent are all within the scope of the present invention.

What is claimed is:

1. A heat-sinking memory module device, comprising:
a memory module board;
a plurality of semiconductor components, said plurality of semiconductor components being deposed on said memory module board; and
a plurality of chips, said chip being deposed on said semiconductor component, said chip having a surface exposed in air.

2. The device according to claim 1,
wherein said plurality of semiconductor components are deposed on a side surface of said memory module board.

3. The device according to claim 1,
wherein said plurality of semiconductor components are deposed on two side surfaces of said memory module board.

4. The device according to claim 1,
wherein a surface of said semiconductor component is connected with said memory module board through tin balls.

5. The device according to claim 1,
wherein a surface of said chip is further connected with a surface of a thermal pad through a thermal interface material (TIM).

6. The device according to claim 5,
wherein said TIM is a gel material with a heat sinking effect.

7. The device according to claim 5,
wherein said thermal pad is made of a material selected from a group consisting of a metal and an alloy.

8. A heat-sinking memory module device, comprising:
a memory module board;
a plurality of semiconductor components, said plurality of semiconductor components being deposed on said memory module board;
a plurality of chips, said chip being deposed on said semiconductor component; and
at least one thermal pad, said at least one thermal pad dissipating heat generated from said plurality of semiconductor components.

9. The device according to claim 8,
wherein said plurality of semiconductor components are deposed on a side surface of said memory module board.

10. The device according to claim 8,
wherein said plurality of semiconductor components are deposed on two side surfaces of said memory module board.

11. The device according to claim 8,
wherein said thermal pad is made of a material selected from a group consisting of a metal and an alloy.

12. The device according to claim 8,
wherein said semiconductor component is connected with said thermal pad through steps of:
(a) smearing said semiconductor components with underfill;
(b) grinding said semiconductor components to expose surfaces of said chips; and
(c) adhering said at least one thermal pad to said surfaces of said chips with a TIM.

13. The device according to claim 12,
wherein said semiconductor components are packaged in step (a) before being ground in step (b).

14. The device according to claim 12,
wherein said TIM is a gel material with a heat sinking effect.
